(19) United States
(12) Patent Application Publication
(10) Pub. No.: US 2026/0285675 A1
(43) Pub. Date: Sep. 24, 2026

(54) VACUUM ENCAPSULATION

(71) Applicant: OBSIDIAN SENSORS, INC., San Diego, CA (US)

(72) Inventors: Sean C. ANDREWS, San Diego, CA (US); Ming YING, San Diego, CA (US); Edward CHAN, San Diego, CA (US); Bing WEN, San Diego, CA (US); Tallis CHANG, San Diego, CA (US)

(21) Appl. No.: 19/478,223

(22) PCT Filed: Apr. 26, 2024
(86) PCT No.: PCT/US2024/026655

§ 371 Date: Oct. 23, 2025

Related U.S. Application Data
(60) Provisional application No. 63/462,937, filed on Apr. 28, 2023.

(51) Int. Cl. B81C 1/00; B81B 7/00

(52) U.S. Cl. CPC B81C 1/00269; B81B 7/0041

(57) ABSTRACT

Vacuum encapsulation on a wafer including: preparing a first substrate by placing a first set of seal ring metals to define a first set of bondlines and solder platforms, the first substrate providing a plurality of device areas; preparing a second substrate by placing a second set of seal ring metals to define a second set of bondlines, the second substrate providing a plurality of covers for the plurality of device areas, wherein each cover encapsulates vacuum; placing solder outside of the first and second set of bondlines; and heating to bond the first and second substrates.

### CROSS-REFERENCE TO RELATED APPLICATIONS

This application claims benefit of U.S. Provisional Application No. 63/462,937, filed Apr. 28, 2023, the entire disclosure of which is herein incorporated by reference.

### BACKGROUND

### Field

The present disclosure relates to vacuum encapsulation, and more specifically, to vacuum encapsulation using cover-to-wafer packaging.

### Background

Micro-electromechanical system (MEMS) devices including uncooled microbolometer sensors may require maintained pressures of less than 10 millitorr for proper performance. This may be achieved by forming a hermetic seal while in a vacuum environment, otherwise known as vacuum packaging. There are many ways by which hermetic seals can be formed, including metallic solder. Commonly, the metallic solder starts within and in contact throughout the bondline (e.g., in-place solder technique).

One method of providing the hermetic seal may involve vacuum encapsulation including wafer-level packaging (WLP) where packaging components are attached to an integrated circuit (IC) before the wafer (on which the IC is fabricated) is diced. A common form of WLP is wafer-to-wafer packaging (WWP), wherein both packaging components, cover and IC, are bonded while in wafer form.

### SUMMARY

The present disclosure discloses vacuum encapsulation on a wafer.

In one implementation, a method for vacuum encapsulation on a wafer is disclosed. The method includes: preparing a first substrate by placing a first set of seal ring metals to define a first set of bondlines and solder platforms, the first substrate providing a plurality of device areas; preparing a second substrate by placing a second set of seal ring metals to define a second set of bondlines, the second substrate providing a plurality of covers for the plurality of device areas, wherein each cover encapsulates vacuum; placing solder outside of the first and second set of bondlines; and heating to bond the first and second substrates.

In another implementation, a vacuum encapsulated device is disclosed. The device includes a first set of seal ring metals, a first substrate, a second set of seal ring metals, and a second substrate. The first substrate is prepared by placing the first set of seal ring metals to define a first set of bondlines and solder platforms. The first substrate provides a plurality of device areas. The second substrate is prepared by placing the second set of seal ring metals to define a second set of bondlines. The second substrate provides a plurality of covers for the plurality of device areas. Each cover encapsulates vacuum. Solder is placed outside of the first and second set of bondlines on or above each solder platform.

Other features and advantages should be apparent from the present description which illustrates, by way of example, aspects of the disclosure.

### BRIEF DESCRIPTION OF THE DRAWINGS

The details of the present disclosure, both as to its structure and operation, may be gleaned in part by Study of the appended drawings, in which like reference numerals refer to like parts, and in which:

FIG. 1 shows one implementation of the Wafer-to-wafer packaging (WWP) in which the solder begins within the bondline;

FIG. 2 shows a cover-to-wafer packaging (CWP) in accordance with one implementation of the present disclosure;

FIG. 3 is a silicon window showing bondline and solder platform areas covered by continuous metal, where the wetting begins;

FIG. 4 is a diagram showing an encapsulation geometry for solder surface diffusion including top and bottom surfaces in accordance with one implementation of the present disclosure;

FIG. 5 is a diagram of an array of devices on a wafer or plate substrate and individual lids in accordance with one implementation of the present disclosure;

FIG. 6 is a flow diagram of a method for vacuum encapsulation on a wafer in accordance with a particular implementation of the present disclosure; and

FIG. 7 is a block diagram of a vacuum encapsulated device in accordance with another particular implementation of the present disclosure.

### DETAILED DESCRIPTION

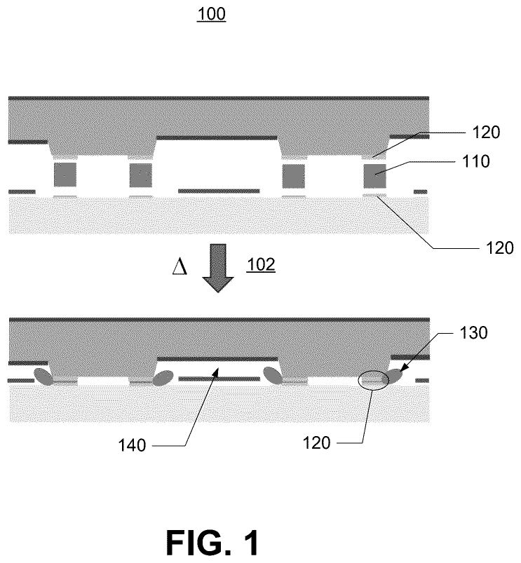

As described above, a conventional method of achieving vacuum encapsulation includes wafer-to-wafer packaging (WWP). FIG. 1 shows one implementation of the WWP 100 in which the solder 110 is formed within the bondline 120. Common solder placement techniques include electrodeposition onto either or both substrates or preformed solder molds are placed over the bondline. However, since the solder 110 is already in the bondline 120 before bonding process begins, the oxide on the surface of the solder, whether formed natively or from processing, must be either removed, avoided, or prevented to create a stable bond. Furthermore, in-place solder 110 may result in excess solder 130 being squeezed out after the two surfaces of the bondline 120 are brought together under force 102, which may require more controlled solder quantity and/or special designs to reduce excess solder ingress into the device cavity 140. Lastly, the in-line solder may restrict the range of temperatures that can be tolerated before the bonding takes place (e.g., to enhance outgassing prior to encapsulation).

Certain implementations of the present disclosure provide for: (1) creating a sealed vacuum cavity without a solder starting within the bondline; (2) placing the solder outside the bondline and spreading it into the bondline while in an inert or vacuum cavity by extending out the seal ring metal past the bondline to create a solder platform on one of the substrates (e.g., the device or window); and (3) enabling the metal solder to form a bond between the two metalized surfaces because the flowing solder in the vacuum cavity is not oxidized.

After reading the below descriptions, it will become apparent how to implement the disclosure in various implementations and applications. Although various implementations of the present disclosure will be described herein, it is understood that these implementations are presented by way of example only, and not limitation. As such, the detailed description of various implementations should not be construed to limit the scope or breadth of the present disclosure.

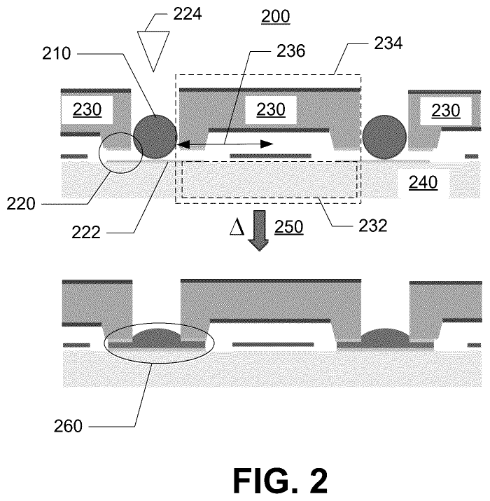

FIG. 2 shows a cover-to-wafer packaging (CWP) 200 in accordance with one implementation of the present disclosure. In FIG. 2, the solder 210 starts outside of the bondline 220 on a solder platform 222 in-between individual silicon covers 230. This implementation allows for the use of inexpensive and low-temperature solder.

In another implementation, the solder need not be placed adjacent to the cover as shown in FIG. 2. For example, the solder may be held in a reservoir 224 above the solder platform 222 and extruded in-situ at any time during the packaging process. Thus, the solder is not in physical contact with either substrate. Accordingly, in this implementation, the device substrate and covers can be heated to temperatures that exceed a reflow temperature of the solder without the hermetic seal forming, which is advantageous for the removal of unwanted gaseous species otherwise removed with use of a getter. In effect, this decouples the timing of the reflow process from the temperature of either substrate. The solder is then deposited onto the solder platform 222 of the device substrate. In some implementations, the solder is extruded from the reservoir (e.g., item 224 in FIG. 2) through holes that are positioned above the solder platform 222 to begin the reflow process. When the solder from item 224 is in contact with the solder platform 222 and the temperature of the substrate reaches the reflow temperature, the reflow process starts, and the hermetic seal is formed shortly thereafter. By having the solder thermally and spatially decoupled from the other substrates, the annealing and reflow processes are likewise decoupled. The substrate temperature may exceed the solder reflow temperature and not start the reflow process because the solder is not touching either of the substrates, thereby removing the need to involve getter materials and the complexity, constraints, and cost associated with their use.

In the illustrated implementation of FIG. 2, the bondline 220 is the joining surface of two substrates 230, 240 with a seal ring metal extending past the bondline 220 to define the solder platform 222 on one of the substrates 240 so that the solder 210 may flow into the bondline 220. In this implementation, the solder 210 is placed laterally outside the bondline 220 onto the solder platform 222. The solder 210 is then heated in a reflow process 250 so that the solder 210 may melt and flow into the bondline 220 as shown in ellipse 260. In this implementation, the reflow process 250 (instead of the force used in the WWP) is used to create the hermetic seal. Thus, the advantages of the illustrated implementation of FIG. 2 include: (1) no force is required during bonding to obviate squeeze-out issues (e.g., item 130 in FIG. 1); (2) the on-wafer uniformity is improved since the evacuation distance is the same for each die (or a device area) 232; and (3) silicon utilization is more efficient to lower the silicon cover cost per device 234. In the above implementation, the evacuation distance 236 is the distance from the center of the cavity to the external system. For WWP, the center of a 200 mm wafer has a distance of 100 mm to the edge of the wafer, which is the maximum evacuation distance. Since each cover is discrete in CWP, the evacuation distance for each device is the same small value (i.e., the center to the edge of the cover (~10 mm) ).

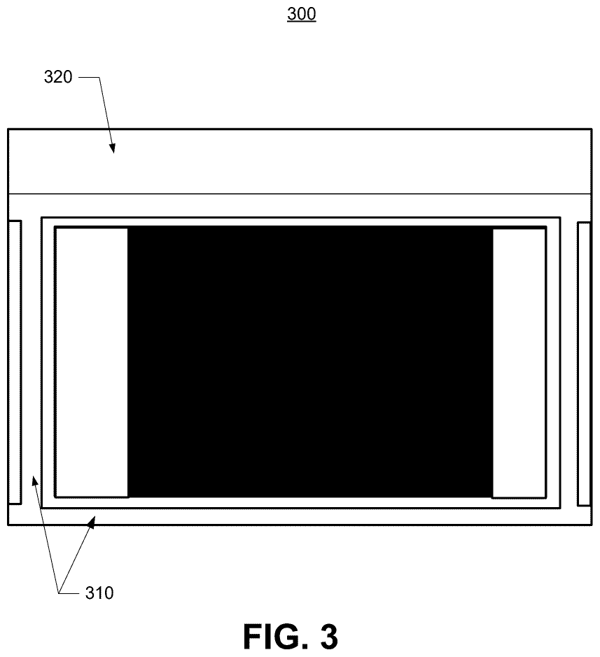

FIG. 3 is a silicon window 300 showing bondline 310 (i.e., the outer metal periphery) and solder platform areas 320 covered by continuous metal where the solder wetting (a process in which metal in the solder bonds with the metal in the device) begins.

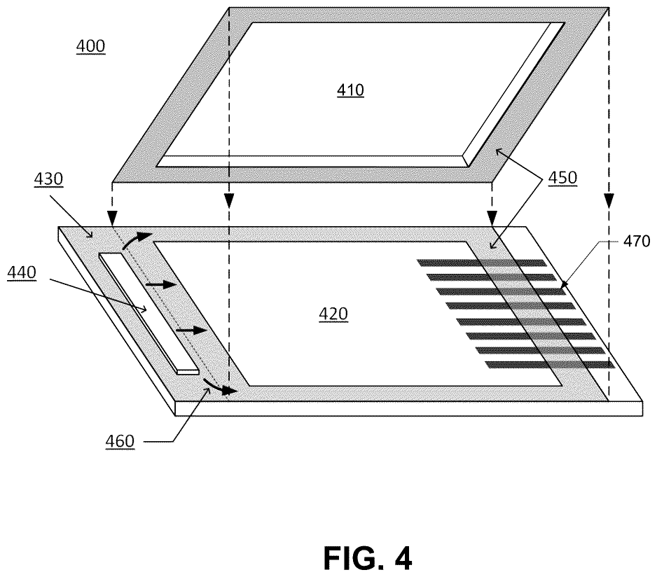

FIG. 4 is a diagram showing an encapsulation geometry 400 for solder surface diffusion including top and bottom surfaces in accordance with one implementation of the present disclosure. In the illustrated implementation of FIG. 4, the top surface is an encapsulation window 410 providing a cavity, and the bottom surface is a device area 420 to be packaged. In other implementations, the position and role of the top and bottom surfaces may be reversed.

In comparing the encapsulation geometry 400 of FIG. 4 to the cover-to-wafer packaging (CWP) 200 of FIG. 2, a solder 440 starts outside of the bondline 450 on a solder platform 430 (defined by the seal ring metals, similar to the solder platform 222 shown in FIG. 2). In the illustrated implementation of FIG. 4, when the solder 440 is heated in a reflow process, the solder 440 melts and flows 460 into the bondline 450 (e.g., about 50 to 500 μm in width) to create a hermetic seal.

In some implementations, the device area 420 is part of a continuous wafer or plate depending on which technology is being used (e.g., silicon-based devices or glass-based devices). In some implementations (e.g., the illustrated implementation of FIG. 4), the surface area of the encapsulation window 410 is smaller than that of the device area 420 since the device area 420 may host other elements including metal pads 470 for electrical interconnects. This allows for a greater number of cover die per wafer than the device substrate. In some implementations, an etched cavity of the encapsulation window 410 is about 50 to 200 μm in depth, for example, to accommodate a device environment volume. In some implementations, a metal frame is used to hold the individual windows in pre-aligned positions (and the metal frame aligned with respect to the device substrate) which can hold the covers in position during handling. In this way, a larger number of devices may be simultaneously packaged since pump-down and heating cycles can be shared among all the devices being bonded.

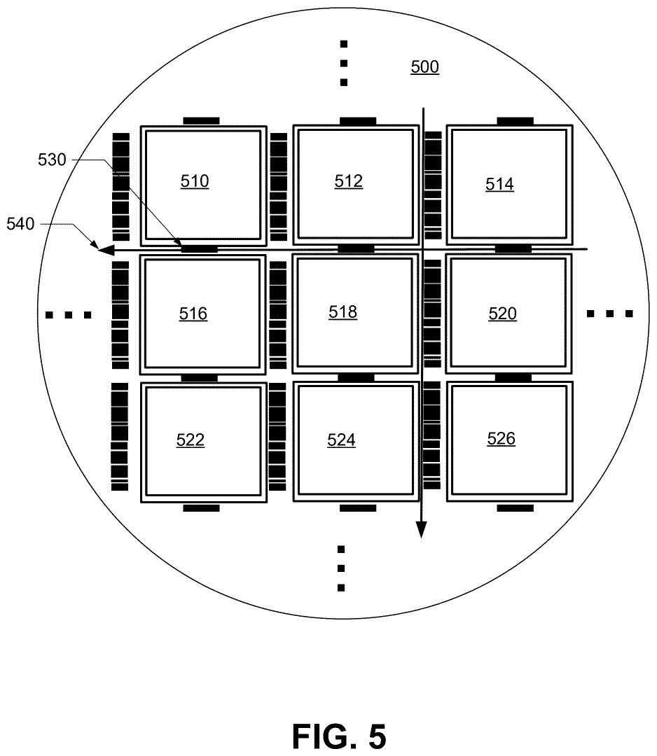

FIG. 5 is a diagram of an array of devices on a wafer or plate substrate 500 and individual lids 510-526 in accordance with one implementation of the present disclosure. Note that the size of the substrate with devices is not limited to traditional wafer processing sizes. In the illustrated implementation of FIG. 5, the substrate aligns with corresponding lids.

In some implementations, the individual lids 510-526 are prepared beforehand and fixed into alignment position with a frame made of metal, glass, or other materials. In other implementations, the solder placement 530 allows flow bilaterally to adjacent device/lid pairs (e.g., lid pairs 510, 516 for solder placement 530). FIG. 5 also shows cut lines 540 (also referred to as dicing streets, singulation avenues, or dividing courts) used for singulation, which is a process of cutting, dicing, or scribing a finished wafer into individual chips. The above-described arrangement may be advantageous compared to wafer-to-wafer bonding, where both device and window (lid) may be continuous wafer forms and may require, post bonding, a cut of the window wafer to expose the connection bonds on the device wafer.

In summary, the vacuum encapsulation method includes:
1. Preparing a pair of substrates with the first substrate providing a device area and the second substrate providing a cover for the device area;
2. Placing seal ring metal on the periphery of the device area;
3. Placing seal ring metal extending past bondline on one of the pair of substrates to define the solder platform areas;
4. Dicing cover wafer into individual die and populating the device substrate with the diced pieces;
5. Placing solder outside of the bondline onto the solder platform next to or in-between individual covers so that the solder may flow into the bondline, wherein the bondline is the joining surface of two substrates;
6. Heating the solder so that the solder melts and flows into the bondline;
7. Waiting while under vacuum for the solder to re-solidify, and then exposing bonded substrates to atmospheric pressures ;
8. Performing singulation of the device areas on the wafer.

It should be noted that not all steps listed above need to be performed for vacuum encapsulation.

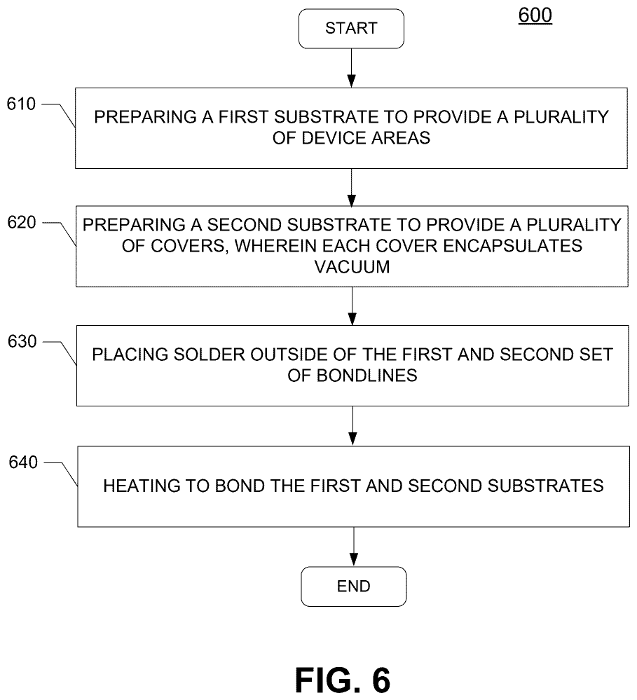

FIG. 6 is a flow diagram of a method 600 for vacuum encapsulation on a wafer in accordance with a particular implementation of the present disclosure. The method includes: (a) preparing a first substrate by placing a first set of seal ring metals to define a first set of bondlines and solder platforms, the first substrate providing a plurality of device areas (step 610); (b) preparing a second substrate by placing a second set of seal ring metals to define a second set of bondlines, the second substrate providing a plurality of covers for the plurality of device areas, wherein each cover encapsulates vacuum (step 620); (c) placing solder outside of the first and second set of bondlines (step 630); and (d) heating to bond the first and second substrates (step 640).

In one implementation, the first set of bondlines and the solder platforms occupy different areas of the first set of seal ring metals. In one implementation, the method further includes dicing the second substrate into the plurality of covers to produce diced pieces of covers. In one implementation, the method further includes populating the first substrate with the diced pieces of covers. In one implementation, the method further includes performing singulation of the plurality of device areas on the wafer. In one implementation, placing the solder outside of the first and second set of bondlines includes placing the solder on the solder platforms next to or in-between adjacent covers of the plurality of covers on the first set of seal ring metals. In one implementation, heating to bond the first and second substrates includes heating to allow the solder placed next to or in-between the adjacent covers to flow from the solder platforms to in between the first and second set of bondlines. In one implementation, placing the solder outside of the first and second set of bondlines includes placing the solder in a reservoir above the solder platform and extruding the solder. In one implementation, the method further includes: allowing the solder to re-solidify under vacuum; and exposing the bonded first and second substrates to atmospheric pressures. In one implementation, the method further includes performing singulation of the plurality of device areas on the wafer.

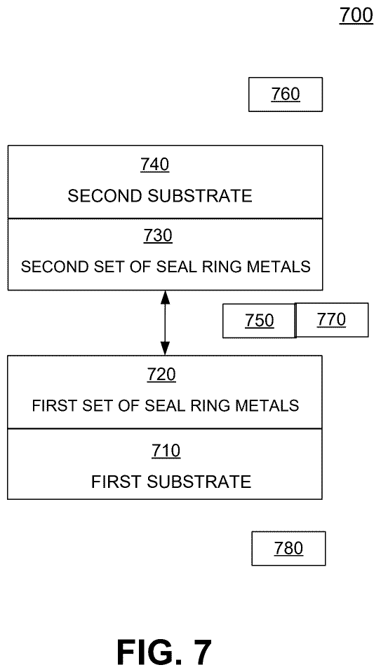

FIG. 7 is a block diagram of a vacuum encapsulated device 700 in accordance with another particular implementation of the present disclosure. In the illustrated implementation of FIG. 7, the device 700 includes a first set of seal ring metals 720, a first substrate 710, a second set of seal ring metals 730, and a second substrate 740. The first substrate 710 is prepared by placing the first set of seal ring metals 720 to define a first set of bondlines and solder platforms. The first substrate 710 provides a plurality of device areas. The second substrate 740 is prepared by placing the second set of seal ring metals 730 to define a second set of bondlines. The second substrate 740 provides a plurality of covers for the plurality of device areas. Each cover encapsulates vacuum. Solder 750 is placed outside of the first and second set of bondlines on or above each solder platform.

In one implementation, the first set of bondlines and the solder platforms occupy different areas of the first set of seal ring metals. In one implementation, the vacuum encapsulated device further includes a dicer 760 to dice the second substrate into the plurality of covers to produce diced pieces of covers. In one implementation, the vacuum encapsulated device further includes a reservoir 770 for holding the solder on or above the solder platform and extruding the solder. In one implementation, the vacuum encapsulated device further includes a singulation device 780 to perform singulation of the plurality of device areas on the wafer.

Those skilled in the art will recognize that the implementations described herein are representative, and deviations from the explicitly disclosed implementations are within the scope of the disclosure. For example, although the above implementations show the seal ring metals extending the bondlines of the first substrate providing a plurality of device areas, the seal ring metals may extend the bondlines of the second substrate providing a plurality of covers instead.

Although the disclosed implementations have been fully described with reference to the accompanying drawings, it is to be noted that various changes and modifications will become apparent to those skilled in the art. Such changes and modifications are to be understood as being included within the scope of the disclosed implementations as defined by the appended claims.

The terminology used in the description of the various described implementations herein is for the purpose of describing particular implementations only and is not intended to be limiting. As used in the description of the various described implementations and the appended claims, the singular forms “a”, “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” and/or “including,” when used in this specification, specify the presence of stated features, integers, steps, operations, elements, and/or components, but do not preclude the presence or addition of one or more other features, integers, steps, operations, elements, components, and/or groups thereof. It will be further understood that the term “exemplary,” when used in this specification, refers to serving as an example, instance, or illustration rather than to commendable or serving as a pattern.

All features of each of the above-discussed examples are not necessarily required in a particular implementation of the present disclosure. Further, it is to be understood that the description and drawings presented herein are representative of the subject matter which is broadly contemplated by the present disclosure. It is further understood that the scope of the present disclosure fully encompasses other implementations that may become obvious to those skilled in the art and that the scope of the present disclosure is accordingly limited by nothing other than the appended claims.

1. A method for vacuum encapsulation on a wafer, the method comprising:
preparing a first substrate by placing a first set of seal ring metals to define a first set of bondlines and solder platforms, the first substrate providing a plurality of device areas;
preparing a second substrate by placing a second set of seal ring metals to define a second set of bondlines, the second substrate providing a plurality of covers for the plurality of device areas, wherein each cover encapsulates vacuum;
placing solder outside of the first and second set of bondlines; and
heating to bond the first and second substrates.

2. The method of claim 1, wherein the first set of bondlines and the solder platforms occupy different areas of the first set of seal ring metals.

3. The method of claim 1, further comprising
dicing the second substrate into the plurality of covers to produce diced pieces of covers.

4. The method of claim 3, further comprising
populating the first substrate with the diced pieces of covers.

5. The method of claim 1, further comprising
performing singulation of the plurality of device areas on the wafer.

6. The method of claim 1, wherein placing the solder outside of the first and second set of bondlines comprises
placing the solder on the solder platforms next to or in-between adjacent covers of the plurality of covers on the first set of seal ring metals.

7. The method of claim 6, wherein heating to bond the first and second substrates comprises
heating to allow the solder placed next to or in-between the adjacent covers to flow from the solder platforms to in between the first and second set of bondlines.

8. The method of claim 1, wherein placing the solder outside of the first and second set of bondlines comprises
placing the solder in a reservoir above the solder platform and extruding the solder.

9. The method of claim 1, further comprising:
allowing the solder to re-solidify under vacuum; and
exposing the bonded first and second substrates to atmospheric pressures.

10. The method of claim 1, further comprising performing singulation of the plurality of device areas on the wafer.

11. A vacuum encapsulated device, comprising:
a first set of seal ring metals;
a first substrate prepared by placing the first set of seal ring metals to define a first set of bondlines and solder platforms, the first substrate providing a plurality of device areas;
a second set of seal ring metals;
a second substrate prepared by placing the second set of seal ring metals to define a second set of bondlines, the second substrate providing a plurality of covers for the plurality of device areas,
wherein each cover encapsulates vacuum, and
wherein solder is placed outside of the first and second set of bondlines on or above each solder platform.

12. The vacuum encapsulated device of claim 11, wherein the first set of bondlines and the solder platforms occupy different areas of the first set of seal ring metals.

13. The vacuum encapsulated device of claim 11, further comprising
a dicer to dice the second substrate into the plurality of covers to produce diced pieces of covers.

14. The vacuum encapsulated device of claim 11, further comprising
a reservoir for holding the solder on or above the solder platform and extruding the solder.

15. The vacuum encapsulated device of claim 11, further comprising a singulation device to perform singulation of the plurality of device areas on the wafer.
